(19) United States
(12) Patent Application Publication
(10) Pub. No.: US 2007/0227383 A1
(43) Pub. Date: Oct. 4, 2007

(54) Soft Lithographic Stamp with a Chemically Patterned Surface

(75) Inventors: Michel Marcel Jose Decre, Eindhoven (NL); Martin Blees, Eindhoven (NL); Patrick Petrus Johannes Van Eerd, Eindhoven (NL); Richard Joseph Marinus Schroeders, Eindhoven (NL); Dirk Burdinski, Eindhoven (NL); Ruben Bernardus Alfred Sharpe, Enschede (NL); Jurriaan Huskens, Enschede (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/570,801

(22) PCT Filed: Jun. 27, 2005
(86) PCT No.: PCT/IB05/52111

§ 371 Date: Dec. 18, 2006

(30) Foreign Application Priority Data
Jun. 30, 2004 (EP) 04103075.0
Mar. 14, 2005 (EP) 05101944.6

(51) Int. Cl. G03F 7/00

(52) U.S. Cl. 101/450.1; 101/453; 101/463.1

(57) ABSTRACT

The present invention provides a soft lithographic stamp (30) and a method for the manufacturing of such a stamp (30). A stamp (30) according to the present invention comprises blocking regions (37) and printing regions (38). The blocking regions (37) are formed of a material which is different from the material the printing regions (38) are formed of and which exhibits a reduced permeability, diffusivity or absorbing or adsorbing capability to the printing compound, such that it prevents or significantly reduces chemical or physical transport or transfer of the printing compound from the blocking regions to a substrate that has to be patterned or printed. In that way, when impregnating the stamp (30) with a printing compound, the printing compound only diffuses into the printing regions (38) and hence, the printing compound is only transferred from the printing regions (38) to the substrate to be patterned and substantially no diffusion of printing compound via air voids (33) between protruding elements (32) will occur.

The present invention relates to methods and apparatus for soft lithography. More particularly the present invention relates to a stamp with a chemically patterned surface which comprises printing regions and blocking regions formed from different materials, and to a method of forming such a soft lithographic stamp.

Soft lithography includes a group of patterning techniques, such as microcontact printing (MCP), microtransfer patterning (MTP) and liquid embossing, which offer easy, fast and cheap reproduction of down to sub-micron sized features on large areas. These methods can in principle be used for depositing or patterning metallic and non-metallic materials, even on curved or flexible substrates in a few processing steps or just in a single simple processing step.

In soft lithographic techniques, features are generated on a surface by using for example a rubber stamp of which the surface comprises a patterned relief. The stamp is usually made of poly(dimethylsiloxane) (PDMS). This material allows for conformal contact with the substrate combined with advantageous chemical and physical properties important for the ink transfer behavior. Stamps are fabricated by casting a pre-polymer on a master with a negative of the desired pattern, curing it, and peeling the cured stamp off the master.

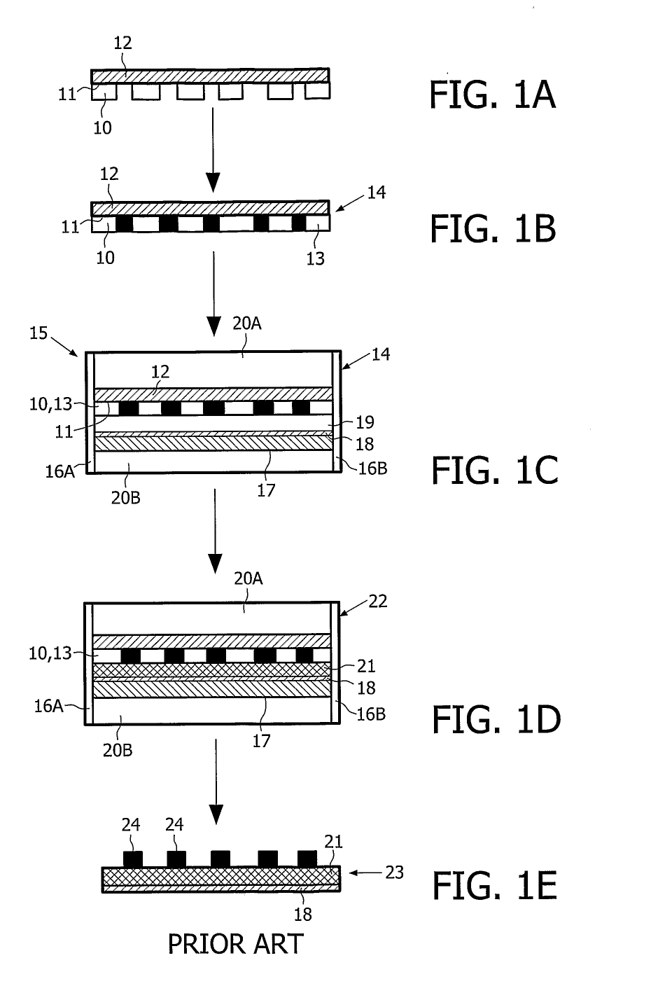

In US-A1-2003/0127002 a method for manufacturing a stamp is described in which multiple layers are employed, each of these layers providing an independent property. Referring to FIG. 1 a flow chart is shown that has items A through E which are representations of intermediate structures produced in the fabrication of the stamp 23 according to US-A1-2003/0127002. At item A, a mould master pattern structure is produced in which a relief pattern 10 of the ink transfer pattern of the stamp 23 to be produced, hereinafter referred to as the pattern 10, is formed on a surface 11 of a supporting substrate 12. The substrate 12 has the properties of imparting stiffness, flatness and permitting adherence by the pattern 10.

The pattern 10 is formed by standard lithographic techniques on the surface 11 in a negative relief, which indicates that the spaces between the pattern features will form the raised relief portions of the final stamp 23. On the surface of the pattern 10, a relatively thin layer 13 of the material that is to become the surface of the stamp 23 is applied. The material siloxane is one example of an appropriate material for layer 13.

The structure as in item B is given the reference designation 14. It now has the pattern 10 on the surface 11 of the substrate 12, with the interstices filled with the material of the layer 13, any excess having been removed so that the surface is made up of embossed elements of the pattern 10 and interstice elements of the material 13, hereinafter referred to as 10-13, and with the structure 14 having been subjected to a partial curing operation, so that it may now be handled for further processing.

Further processing involves, as illustrated in item C, the positioning of the structure 14 in a mould type apparatus for an injection operation. In item C the structure 14 is positioned in the mould 15 having sides, such as 16A and 16B, arranged such that the structure 14 is supported and surrounded. Further in the illustration in item C, a supporting plate 17 is positioned in the bottom opening of the mould 15 and a relatively thin layer 18 of a flexible sheet metal material that will serve as a bottom surface of the stamp 23 is placed over the supporting plate 17. The relative positioning provides an internal gap 19 in the mould 15 between the thin layer 18 and the 10-13 face of the structure 14. The mould member 15 has a top 20A and a bottom 20B. There is the capability, not shown, for injecting material into and filling the gap 19 of the structure of item C.

Referring to item D, the gap 19 of item C is filled with a precursor mix of a bulk producing material 21 that will on curing impart the bulk structural properties of the stamp 23 and cause the optimized adhesion properties of the material 13 to adhere to the bulk material 21. A satisfactory material for the precursor mix is a fluid solution of the material siloxane. Where the material 13 is only partially cured at the intermediate structure 14 stage, a cross reaction occurs at the interface and a superior adhesion to the material 21 in the structure in item D is achieved.

Upon curing, the structure labeled 22 is in the mould 15 ready for removal of the top 20A, bottom 20B and sides 16A and 16B as in item D. The intermediate structure 22 includes the supporting substrate 12 layer, the interstices filled pattern 10-13 layer, the cured bulk layer 21, the thin layer 18 and the supporting plate 17. The finished stamp 23 is illustrated in item E.

After removal of structure 22 from the mould 15, the supporting plate 17 is removed leaving exposed the thin layer 18 on one face. On the other face, the supporting substrate 12 is removed along with the master pattern 10. An operation either simultaneously with removal of the supporting plate 17 or etching is conducted at the 10-13 surface, removing the embossed portions of the master 10 and exposing a positive relief siloxane element pattern 24, each element of which is adhering the optimized adhesion properties to the bulk siloxane body of the stamp 23.

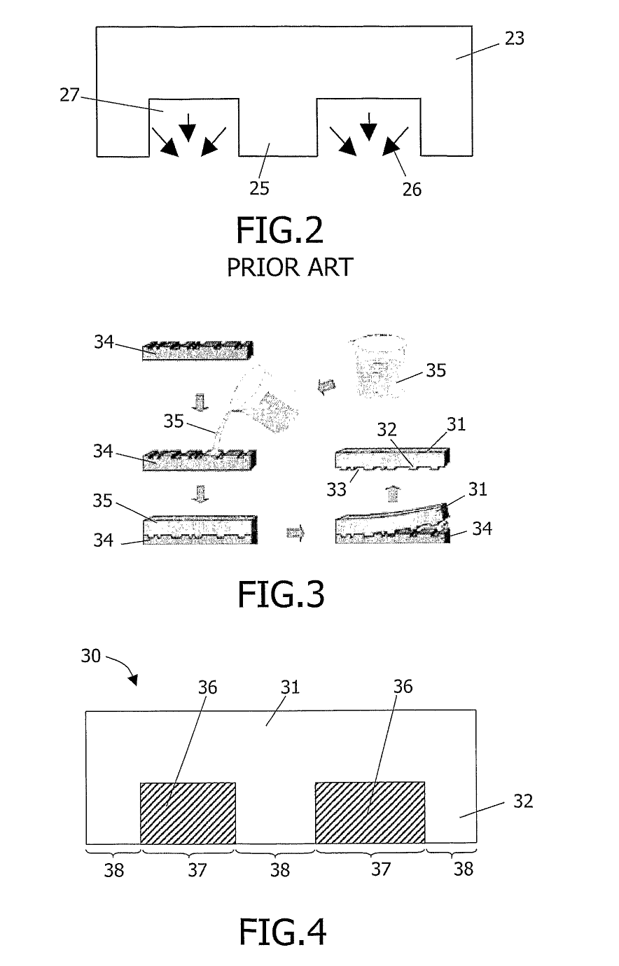

The surface of the stamp 23 essentially comprises a set of microscopic protruding elements 25, as can be seen in FIG. 2, which shows a simplified schematic illustration of the stamp 23. FIG. 2 furthermore illustrates gas-phase diffusion of material (indicated by arrows 26) of printing compounds from the stamp 23 to a substrate that has to be patterned, which can occur via the air voids 27 between the protruding elements 25 of the stamp 23. This can lead to unwanted spots and misaligned patterns on the surface of the substrate that has been printed. A further known disadvantage is that unwanted contact can occur between the recessed areas and the surface to be patterned due to the combination of pressure, and the size and height of the protruding elements 25, and the lateral distance between the protruding elements 25. Furthermore, even if unwanted contact can be avoided, gas-phase or surface diffusion can still occur from recessed areas or voids to unwanted areas of the substrate.

It is an object of the present invention to provide a methods and apparatus for a stamp, which shows reduced and preferably no unwanted diffusion of printing compounds from the stamp to a substrate that has to be printed via air voids between protruding elements of the stamp or unwanted contact between recesses and the substrate that has to be patterned.

The above objective is accomplished by a device and method according to the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

In a first aspect of the present invention, a soft lithographic stamp for use with a printing or marking compound to generate a printed area is provided. Throughout the present document, the terminology “printing compound” is used. This is meant to include both materials as normally used for printing and marking compounds, i.e. materials which are used for printing, but which may be removed later on, such as for example materials used for printing a mask, e.g. for etching, which mask is removed after carrying out the etching. The stamp according to the present invention comprises a stamp body, at a surface of which a first region with a first material and a second region with a second material are present. One of those first and second regions corresponds to the printed area to be generated on the substrate. The first material has a bulk, and particularly constitutes the main portion of the stamp body. The second material possesses an adsorption and storage capability for the printing compound that are different from those of the first material. As a result, on printing, the printing compound is transferred selectively from either the first region or the second region to the substrate. The second material is adjacent to and abuts the first material for reducing or preventing sideways enlargement of the printed area. In use, i.e. when printing by using the soft lithographic stamp with the printing or marking compound, f.i. the second material prevents or significantly reduces chemical or physical transport or transfer of printing or marking compound from the blocking regions to a substrate to be patterned or printed. Then, the second material acts as a means for reducing or preventing sideways extrusion of printing or marking compound from the printing regions. The first and the second materials may be solid materials. The storage capability may be a permeability capability, a diffusivity capability or an absorption capability for the printing compound.

In a preferred embodiment, the first region acts as the printing region and the second region acts as a blocking region. This has the advantage that the material of the printing regions acts as a reservoir for molecules from the printing or marking compound as these molecules are stored, e.g. absorbed, in the bulk of the stamp. The molecules of the printing compound diffuse to the surface of the stamp as they are consumed during printing or patterning of a substrate. At the places of the substrate to be printed, i.e. where the printing regions of the stamp contact the substrate, preferably a monolayer of the printing compound is formed. At the places of the substrate that are not to be printed, i.e. where the blocking regions of the stamp contact the substrate, no or very little printing compound is transferred from the blocking regions towards the substrate as the blocking regions act as a transport barrier reducing or preventing the printing compound to be transported across. In that way, reduced or substantially no unwanted physical or chemical transport or transfer of printing compound occurs towards the places of the substrate that do not have to be printed. Hence, a reduced number of, or substantially no unwanted spots are present in the print on the substrate and thus an enhanced quality of the printed substrate may be achieved. Moreover, the stamp can be used several times without re-inking.

The stamp may comprise a mould with protruding elements. The mould and protruding elements may be made either from material for printing which easily stores, e.g. absorbs, printing compound, or from material with reduced permeability, diffusivity, absorption or absorption capability for blocking printing compound. Material is introduced in between the protruding elements on the mould. In the first case, the material in between the protruding elements consists of material with reduced permeability, diffusivity, absorption or absorbing capability for printing compound, and in the second case, the material in between the protruding elements is material which easily stores, e.g. absorbs, printing compound.

The first material may for example be a polymer material, such as any of poly(dimethylsiloxane) or hydrogel. It has suitably a sufficient elasticity for printing, such as usually provided in the field of stamps. It is not excluded that the first material is a mixture of two or more compounds of different nature, or that it contains any desired additive. Preferably, the polymer material is cross-linked into a polymer network. The second material may for example be any of a metal, a hydrogel, an oxide, a polymer, glass, quarts, an elastomer, a resin, a natural rubber or silicon. The second material may be a modification of the first material, such as obtained in an oxidation or other modification step. Particularly, the modification may be achieved with a plasma treatment with a suitable plasma gas as known per se. The plasma gas for instance comprises oxygen for oxidation of the first material, or fluorinated compounds (f.i. CF₄) to obtain fluoridation, or alternative nitrogen, chlorinated compounds and the like. It is not excluded that a third material is used in addition to the second material, said third material being laminated to or adsorbed on the second material. It is not excluded that the second and/or the third material is present in the form of a monolayer. Particularly interesting is the combination of an oxide as the second material and a suitable monolayer or multilayer adsorbed thereon. The properties of the blocking region may be tuned with a suitable choice of the adsorbed third material.

The stamp obtained according to some embodiments of the present invention may have a geometrically essentially flat surface area or a surface area having a shape in accordance with the shape of the surface to be printed, e.g. a curved shape. Voids in between protruding elements on the mould may or may not be completely filled with filling material, in accordance with different embodiments of the present invention. Blocking regions and printing regions are formed of different materials. The blocking regions reduce or prevent unwanted diffusion of a printing compound from the stamp to a substrate to be patterned via air voids between protruding elements of the stamp and they furthermore reduce or prevent unwanted contact between the recessed areas and the substrate to be patterned, which would also lead to unwanted diffusion of printing compound to the substrate.

In one embodiment, the blocking regions may be formed of a patterned barrier film (of second or blocking material) which preferably may have a thickness of 100 nm or less. Preferably, the thickness is even less than 50 nm. Most preferably, the thickness is in the order of 10-30 nm, so as to reduce the unflatness. The patterned barrier film is applied on a substantially flat printing mould, or a printing mould having a surface with a shape corresponding to the shape of the surface of the substrate to be printed, the mould being made of first material suitable for printing. In this case, the stamp does not have geometrically substantially flat surface area. An advantage of this embodiment, however, is the easy manufacturing of the stamp. Printing is performed by first material touching the substrate through voids in the patterned barrier film.

In another embodiment, the barrier film is provided by selective modification of the first material. In this case, the stamp body does have a geometrically substantially flat surface area, at least if not bent. Suitably, the barrier layer is provided with an additional passivating layer. This passivating layer will have substantially the same pattern as the barrier layer. It may be provided by adsorbing a suitable monolayer onto the barrier layer. The passivating layer may be a surface modifying agent in addition to its passivating function. The passivating function is needed particularly if the second material is a modification of the first material that includes siloxane groups, and particularly PDMS and related materials. The PDMS allows diffusion of groups, units or individual compounds within the material. This leads thereto that the modified PDMS compounds or units (i.e. the second material) on the surface are with time diffused into the bulk of the first material and replaced by non-modified PDMS (the first material). However, by provision of a passivating layer (third material in general) that is adsorbed to the modified PDMS, the modified PDMS is kept in place. The binding may be herein both chemical binding and physical binding. A most suitable modified PDMS appears to be the oxidized PDMS.

The passivating layer may be a monolayer compound such as an alkanethiol, a silane, a trimethoxysilane, a trichlorosilane, an acid such as a phosphonic acid, a sulphonic acid or a carboxylic acid, an activated acid such as an acid chloride. Such functional groups may be used for binding to the modified PDMS. Alternatively, the monolayer comprises more than one, particularly two functional groups: one for binding to the second material, and another to provide a modified surface structure. In such a case, it is however important to select such materials that do not or not substantially adsorb to the non-modified portion of the surface. In case adsorption to the non-modified portion of the surface cannot be avoided, it should be reversible and sufficiently less strong than to the modified portion of the surface, such that the adsorbed material can subsequently be removed selectively from the non-modified areas to provide only the modified portion of the surface with a passivating layer. The passivating layer may alternatively be a metal or a metal compound such as a metal oxide. In a suitable embodiment, the metal or alloy is provided by electroless deposition.

It is an advantage of a stamp according to the present invention that it is suitable e.g. for manufacturing a semiconductor device, as it is suitable for defining a micron-size pattern. In case of use of a stamp according to the present invention for manufacturing a semiconductor device, the printing compound may for example consist of material suitable for forming a mask during a subsequent etching step. A stamp according to the present invention may also be used e.g. for manufacturing printed circuit boards, in which case the printing compound may for example consist of electrically conductive material, and the printed pattern may form the leads on the circuit board.

The stamp of the invention may be used separately, but also in combination with a larger printing apparatus. Such an apparatus is for instance a wave printer as disclosed in WO-A 2003/099463. The wave printer provides local pressure to the stamp from its back side so as to bring a local area of the stamp in contact with a substrate. Subsequently, a neighbouring local area is brought in contact with the substrate, and so on in a manner of a wave. Particularly a stamp with a barrier layer protected with a passivating layer is suitable therefore. It has been found that with such a stamp a pattern is accurately transferred, even if the barrier layer, often a somewhat brittle layer, is put under external pressure as a consequence of bending.

In a second aspect of the invention, a method for forming a soft lithographic stamp for use with a printing compound to generate a printed area is provided. The method comprises:

providing a moulded stamp body from a first material, which stamp body is provided with a surface;

providing a second material in a patterned manner so as to constitute first regions and second regions on the surface of the stamp body, in which first regions the first material is present at the surface and in which second regions the second material is present at the surface,

wherein the second material abuts the first material so as to prevent sideways enlargement of the printed area and is chosen to possess a storage capability and an adsorption capability for the printing compound that are different from those of the first material.

With the method, stamps of the invention can be made in a reliable manner. Most suitably, the second material acts herein as a blocking region. This blocking regions significantly reduce or prevent the printing compound from being transported to the substrate to be printed. Thus, printing compound is transported substantially only from the printing regions toward the substrate. In that way, the quality of the printed substrate is enhanced.

In one embodiment, the moulded stamp body is formed with protruding elements and by filling spaces between the protruding elements with the second material. The stamp such obtained has a geometrically essentially flat surface area. Blocking regions and printing regions are formed of different materials. The blocking regions significantly reduce or prevent unwanted diffusion of a printing compound from the stamp to a substrate to be patterned, via air voids between protruding elements of the stamp and they furthermore significantly reduce or prevent unwanted contact between the recessed areas and the substrate to be patterned. Suitably, the second material forms the blocking regions, but the reverse is not excluded, particularly since the second material may have a bulk of its own.

In another embodiment, the second material is provided by modification of the first material. Oxidation, fluorination, chlorination are suitable methods that can be carried out with plasma techniques as known to the skilled persons. Other chemical reactions, such as substitutions of functional groups, crosslinking and bonding of additional molecules are not excluded.

In a modification hereon, the thin film of second material is patterned using a direct write technique, for instance with a focused ion beam. This allows the provision of any desired pattern. The direct writing may be used for patterned removal of the second material. Alternatively, the direct writing could be applied for local oxidation of the first material, or even for local deposition of a suitable material. The direct writing is preferably applied in combination with a plasma technique.

Interestingly, the provision of a stamp with a local barrier material allows the use of a single stamp structure for several inks. This can be embodied in at least two ways: in a first manner, several barriers of different materials or barriers covered with passivating layers of different materials are present on the stamp. Each of the different materials is chosen such that it has a preferential affinity for an ink. The inks will then adsorb selectively, or can after adsorption easily be removed from some portions of the stamp surface. In a second manner, the barrier layer extends so far as to expose local portions of the stamp surface only. The diffusion of ink into the stamp may then be limited, such as for instance with short contact times. Then, after a first patterning step with a first ink, the first ink left behind in the stamp may be removed, and a second ink can be applied in and on the stamp.

It is observed that the direct write technique allows the use of suppliers in the manufacturing of the stamp. Such a supplier may manufacture the stamp with the first and the second material. The user may then carry out the step of adsorbing one or more passivating layers (third materials) with specific barrier or affinity properties to the ink. This enables that specific application-related information of the user can be kept secret.

According to a further aspect, the present invention provides a method of manufacturing an electronic device comprising generating a printed area on a substrate, particularly with the stamp of the invention.

Generating a printed area on a substrate may comprise applying the printing compound onto the stamp, rinsing the stamp with a suitable rinsing material, such as for example water or a solvent, so as to remove printing compound from the surface of the stamp, and bringing the stamp into contact with the substrate at least once, thereby transferring printing compound from the printing regions onto the substrate and substantially not transferring printing compound from the blocking regions onto the substrate. Bringing the stamp into contact with the substrate may be done repetitively without applying the printing compound onto the stamp in between. Every time the stamp is brought into contact with the substrate, printing compound stored in the bulk of the printing areas of the stamp is transferred onto the substrate.

The printing compound may be electrically conductive, for example when used in the manufacturing of electronic devices, such as printed circuit boards (PCBs) for example, where area or pattern printed onto the substrate may be lead lines on the PCB. Alternatively, the printing compound may consist of a material suitable for being used as a mask. This may for example be used in semiconductor processing, where the printed area generated by the printing according to the present invention may be used during subsequent processing steps as a mask, e.g. for etching.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

FIGS. 1A-E show a flow chart which depicts intermediate structures produced in the fabrication of a stamp according to the prior art.

FIG. 2 is a schematic illustration of a stamp according to the prior art.

FIG. 3 illustrates an embodiment of part of the manufacturing process of a stamp according embodiments of the present invention.

FIG. 4 is a schematic illustration of a stamp according to a first embodiment of the present invention.

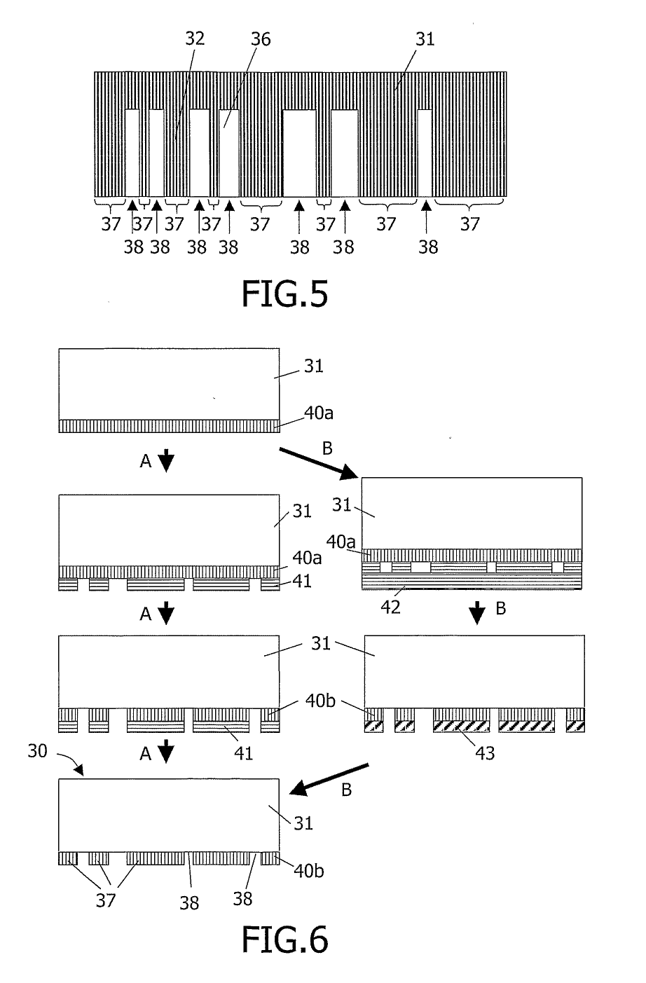

FIG. 5 is a schematic illustration of a stamp according to a second embodiment of the present invention.

FIG. 6 is a schematic illustration of the processing of a stamp according to a further embodiment of the present invention;

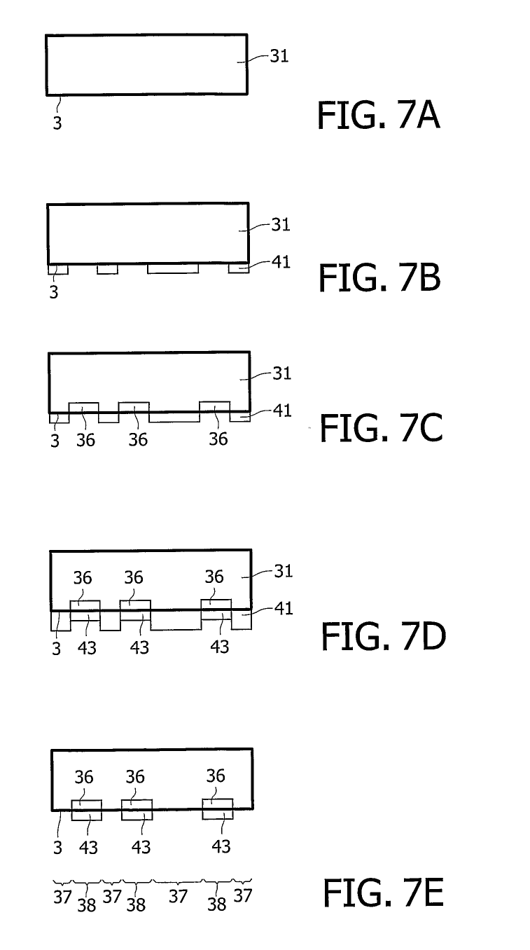

FIGS. 7A-E show a schematic illustration of the processing of a stamp according to another embodiment of the invention.

In the different Figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The present invention provides a chemically patterned stamp and a method for manufacturing such a stamp. A stamp according to the invention shows a reduced unwanted diffusion or does not show unwanted diffusion of printing compounds from the stamp to a substrate that has to be patterned via air voids between protruding elements of the stamp or unwanted contact between these air voids and the substrate to be patterned.

FIG. 3 and FIG. 4 illustrate subsequent steps in the manufacturing of the stamp 30 according to a first embodiment of the invention. During the manufacturing process, firstly, a mould (also referred to as stamp body) 31, comprising protruding elements 32 and air voids 33 in between these protruding elements 32, is formed. This may be done according to any suitable method, known by a person skilled in the art, for forming a stamp.

For example, according to a first embodiment of the present invention, a possible stamp replication process is illustrated in FIG. 3. A master 34 with a negative of the desired pattern is cast with a material suitable for printing with a printing compound, for example a pre-polymer 35. The pre-polymer may for example be a liquid poly(dimethylsiloxane) (PDMS) pre-polymer, or another suitable material. The pre-polymer 35 is then cured under suitable curing conditions as known to a person skilled in the art. Next, the rubber or elastomeric mould 31 formed from the cured pre-polymer 35 is peeled off the master 34.

In a next step, which is schematically illustrated in FIG. 4, the air voids 33 between the protruding elements 32 are filled with a filling material 36. According to the invention, the filling material 36 is different from the material the mould 31 has been formed of. The filling material 36 has a reduced or substantially no storing capability, e.g. permeability, diffusivity, or absorption, nor adsorption capability for printing compounds compared to both the protruding elements 32 and the air voids 33 in between the protruding elements 32, or a storing capability, e.g. permeability, diffusivity, or absorption, or adsorption capability for a printing compound which is sufficiently lower than the storing capability, e.g. permeability, diffusivity, or absorption, or adsorption capability of both the protruding elements 32 and the air voids 33 in between the protruding elements 32 for that printing compound. The difference between the storing capability, e.g. permeability, diffusivity, or absorption capability, or adsorption capability for the printing compound of the filling material 36 and that of the mould 31 is difficult to quantify in general, as it depends on the materials used. The choice of filling material 36 and the material to form the mould 31 should be such that unwanted transport of the printing compound from the blocking regions 37 to the substrate to be printed or patterned is avoided or at least reduced. Also the contact time between the stamp 30 and the substrate has to be taken into account.

Hereinafter, permeability and diffusivity will be explained for different kinds of materials.

Generally, the molecular transport of a species through another species is described by molecular diffusion, using Fick's law:

$$J = - D \frac{ⅆ C}{ⅆ x}$$

wherein J is the flux (moles/s/m²) and D is the diffusion coefficient (m²/s).

When speaking about gas/vapor, sometimes the term permeability may be used by rewriting Fick's law:

$$J = - K \frac{ⅆ p}{ⅆ x}$$

wherein dp/dx is the gradient of partial vapor pressure and K is the permeability:

$$K = D \frac{ⅆ C}{ⅆ p}$$

wherein dC/dp is the solubility coefficient of the material. The permeability described above, however, is quite different in nature from that of porous materials or from the diffusivity of species by molecular diffusion.

In porous materials, liquid permeability is defined by Darcy's law:

$$Q = \frac{k μ A Δ P}{L}$$

wherein Q is the volumetric flow rate across the material, k is the specific permeability (in darcys or m²), μ is the viscosity, αP the pressure difference applied on the material, A the area on which the pressure is applied to drive the liquid through the porosity and L the thickness of the material.

The permeability, diffusivity, or absorption or adsorption capability of the filling material 36 should be sufficiently lower than that of the material the mould 31 has been made of, such that the printing compound material that diffuses across it, from the bulk of the lithographic stamp, to the regions on the substrate that are not to be printed is not sufficient to deteriorate the printing result. Or more in general, the filling material 36 should reduce or not significantly allow the chemical or physical transport of the printing compound to the substrate to be printed. This is difficult to quantify, because it may depend on the total time of contact between the stamp 30 and the substrate that has to be printed or patterned, and on the selectivity of the subsequent use that is made of the printing compound.

For example, when using PDMS for forming the printing regions 38 of a stamp 30 and a resist such as e.g. SU-8 for forming the blocking regions 37, alkanethiols or other thiolated molecules that are used as printing compound do not permeate or diffuse through the SU-8 barrier 36 significantly enough to cause observable printing compound deposition at the location of the blocking regions 37 even after several minutes of contact between the stamp 30 and the substrate. The resist SU-8 used in this example is a negative, epoxy-type, near-UV photoresist based on EPON SU-8 epoxy resin (from Shell Chemical) that has been originally developed, and patented (U.S. Pat. No. 4,882,245 and others) by IBM. For most materials given below, the solubility, and diffusivity of the printing compound molecules through the barrier or filling materials 36 is so low that one can consider that they are impenneable for the printing compounds.

In practice, the permeability of metals and oxides, which may be used as the filling material 36, for monolayer forming molecules and etchants, which may form the printing compound, may be substantially zero, unless there are cracks or pinholes in the metal or oxide layer.

The filling material 36 may for example be a metal, such as e.g. Au, Ti, Cu, Pd or Cr, an oxide, such as e.g. Ta₂O₅ or SiO₂, a polymer, such as e.g. Novolac, poly(methyl methacrylate) (PMMA) or polystyrene (PS), a hydrogel, such as e.g. polyacrylamide or carboxymethylcellulose, glass, quartz, elastomers, resins, natural rubber or silicon. In this way, on the one hand blocking regions 37 for printing compounds are formed, and on the other hand printing regions 38 are formed, and a chemically patterned stamp 30 is obtained with a geometrically essentially flat surface area. Blocking regions 37 and printing regions 38 are formed of different materials. The blocking regions significantly reduce or prevent unwanted diffusion of a printing compound from the stamp to a substrate that has to be patterned, via air voids between protruding elements of the stamp and they furthermore significantly reduce or prevent unwanted contact between the recessed areas and the substrate to be patterned.

When the stamp 30 is impregnated with the printing compound, the printing compound diffuses into the printing regions 38 but substantially not or in a significantly reduced amount into the blocking regions. After rinsing, substantially all the remaining printing compound on the surface of the blocking regions 37 is removed. When exerting some pressure on the stamp 30 for patterning the substrate, printing compound diffused into the printing regions 38 is pressed out to form a pattern on the substrate. Hence, the printing compound is only transferred from the printing regions 38 to the substrate that has to patterned. A reduced amount of printing compound, and preferably substantially no printing compound is transferred at locations at the printing surface of the stamp where blocking regions 37 out of filling material 36 are present.

For example, in case of microcontact printing, the chemically patterned stamp 30 may be impregnated with a long chain alkylthiol as the printing compound. Since the filling material 36 shows reduced or substantially no permeability toward the thiol, reduced amounts of thiol or substantially no thiol diffuses into the blocking regions 37. The stamp 30 is then rinsed to remove the remaining thiol at the blocking regions 37. Hence, thiol will only be transferred from the printing regions 38 to the substrate to be printed and a reduced amount of thiol or substantially no thiol will be transferred from blocking regions 37. In that way, both contact in unwanted areas and diffusion transport of the printing compound may be significantly reduced or prevented.

One difference between the chemically patterned stamps 30 according to the present invention and the stamps according to the prior art is that conventional stamps have geometrically patterned surface areas, while a stamp 30 according to the present invention has a geometrically substantially flat surface area and is chemically patterned. An advantage of a stamp 30 according to the present invention is that reduced or substantially no unwanted transfer occurs of printing compound from the stamp 30 to the substrate that has to be printed, e.g. via air voids 33 in between protruding elements 32, as they are filled with a filling material 36 that has reduced or substantially no permeability for the printing compound. Hence, a reduced amount of unwanted spots or substantially no unwanted spots will be present in the resulting printed pattern, and well-aligned printed patterns may be achieved. Furthermore, reduced or substantially no unwanted contact will occur between recesses or air voids 33 and the substrate that has to be patterned when using a stamp 30 according to the present invention.

An important feature of the stamp 30 according to this invention is that the material that forms the printing regions 38 acts as a reservoir for molecules from the printing compound as these molecules are stored, e.g. absorbed in the bulk of the printing regions 38. The molecules of the printing compound diffuse to the surface of the stamp 30 as they are consumed during printing or patterning of a substrate. At the places of the substrate to be printed, i.e. where the printing regions 38 of the stamp 30 contact the substrate, a monolayer of the printing compound is formed. At the places of the substrate that do not have to be printed, i.e. where the blocking regions 37 of the stamp 30 contact the substrate, a reduced amount of printing compound, or substantially no printing compound is transferred from the stamp 30 to the substrate as the blocking regions 37 act as a transport barrier significantly reducing or preventing the printing compound to be transported across. In that way, reduced or substantially no unwanted physical or chemical transport or transfer of printing compound occurs to the places of the substrate that do not have to be printed. Hence, reduced or substantially no unwanted spots are present in the print on the substrate and thus an enhance quality of the printed substrate is achieved.

An additional advantage of the stamp 30 according to the invention is that the filling of the voids 33 increases the robustness of the stamp 30 in the sense that collapse or buckling of the stamp 30 when put under pressure is avoided.

As an example of the first embodiment, firstly, a mould 31 is formed which has a deep relief, i.e. a relief with a depth d of >16 μm. The air voids 33 of the mould 31 are filled with a filling material 36, such as for example a blocking resist. After impregnation of the stamp 30 in a printing compound such as e.g. a thiol, and after a rinse with a rinsing compound, e.g. ethanol, the only regions of the stamp 30 that will be effectively printing are the printing regions 38. Blocking regions 37 form blocking areas with respect to the printing compound.

According to a second embodiment of the present invention, the materials system may be inverted, i.e. the mould 31 is made from a material which has a low or substantially no storage capability, e.g. permeability, diffusivity, or absorption capability nor adsorbing capability for the printing compound, and the filling material 36 has a high storage capability, e.g. permeability, diffusivity, or absorption capability for the printing compound. The mould 31 may, in this case, for example be made of a stiff material with rather deep aspect ratio, such as for example glass or Si. The air voids 33 in the mould 31 are filled with a filling material 36. In this example, the filling material 36 may, for example, be PDMS (see FIG. 5) and hence, the printing regions 38 may now be formed out of the filling material 36, while the blocking regions 37 are formed out of the mould material. An advantage of this configuration is that a stiff bulk material may be used to enhance still more the robustness of the stamp 30.

In a specific example of a stamp 30 according to the second embodiment, the mould 31 may be formed of PDMS and the filling material 36 may be a hydrogel. The chemically patterned stamp 30 may be impregnated in an aqueous solution comprising an etchant that is compatible with, and will therefore not degrade, the hydrogel. Furthermore, the etchant may preferably not affect or degrade the mould 31. Examples of suitable etchants may for example be KCN/KOH or ferricyanide/thiosulfaat/KOH in case the filling material 36 is Au, or FeCl3/HCl in case the filling material 36 is Cu or Pd.

The etchant diffuses into the printing regions 38 of the stamp 30 comprising the filling material 36, i.e., in the example given the regions comprising hydrogel, and does substantially not, or only in very small amounts, diffuse into the blocking regions 37 formed out of mould material. The stamp 30 may be rinsed with a suitable rinsing material such as e.g. water, through which any remaining etch solution at the surface of the blocking regions 37 are removed. The stamp 30 may then be contacted with e.g. a thin film such as for example a thin metal film. The etching reaction may, in that way, be confined to the area of the thin film in contact with the printing regions 38 comprising the filling material 36, thus etching away part of the thin metal film and creating a metal pattern.

In a further embodiment, an alternative is described for manufacturing moulds according to the first and second embodiment. In this embodiment, the mould 31 is a flat stamp for example of material with a high storage capability, e.g. permeability, diffusivity, or absorption capability, to a printing compound, covered with a thin barrier film 40a having low or substantially no storage capability, e.g. permeability, diffusivity, or absorption capability nor adsorption capability to the printing compound, or a storage capability, e.g. permeability, diffusivity, or absorption capability for the printing compound which is sufficiently lower than the storage capability, e.g. permeability, difflisivity, or absorption capability of the mould 31. The difference between the storage capability, e.g. permeability, diffusivity, absorption or adsorption capability for the printing compound of the filling material 36 and that of the mould 31 is difficult to quantify, as it depends on the materials used. The choice of filling material 36 and the material to form the mould 31 should be such that unwanted transport of the printing compound from the blocking regions 37 to the substrate to be printed or patterned is avoided or at least reduced. Also the contact time between the stamp 30 and the substrate has to be taken into account.

The thin barrier film 40a may, for example, have a thickness of a few tens of nanometers, for example 50 nm or less, and may for example be a metal or oxide layer. The thin barrier film 40a is then structured. This may be done in any of different suitable ways. Hereinafter, two possible structuring processes are described (see FIG. 6).

A first method is to use e.g. a photoresist (FIG. 6, arrows A). The photoresist may be deposited onto the thin barrier film 40a by means of any suitable deposition technique known by a person skilled in the art. Thereafter, a mask (not shown) is applied to align a pattern onto the thin barrier film 40a. Thin barrier film 40a may be formed of multiple layers of different materials, e.g. metal, where a first layer is and adhesion layer and the second or outer layer has a barrier function or another function such as to cap or passivate the surface. The photoresist is then illuminated through the mask e.g. by means of UV light. After illumination, the photoresist is developed by which either the illuminated parts of the photoresist (positive resist) or the non-illuminated parts of the photoresist (negative resist) are removed, depending on which type of photoresist has been used. Patterning of the thin barrier film 40a is then performed using the developed photoresist 41 as a mask, after which the developed photoresist 41 is removed, resulting in patterned thin barrier film 40b as illustrated in FIG. 6.

A second way to pattern the thin barrier film 40a is by using a second stamp 42 that adsorbs an etch-resistant monolayer 43 and deposits the etch-resistant monolayer 43 onto the thin film barrier 40a (FIG. 6, arrows B). For coinage or noble metals such as e.g. Cu, Ag, Au, the etch-resistant monolayer 43 may comprise organic thiols, thioethers and comparable monolayer forming molecules known to those skilled in the art the such as for example octadecylthiol. For oxide forming metals such as e.g. Ti, Ge, Al, and Si, the etch-resistant monolayer 43 may comprise reactive silyl-terminated organic monolayer forming molecules, phosphonic acids, sulfonic acids or carboxylic acids. The examples given are only meant as an example and are not limiting to the invention.

The parts of the thin film barrier 40a which are not covered by the etch-resistant monolayer 43 are then etched away by any suitable method, and the etch-resistant monolayer 43 is removed, either chemically, using e.g. an oxidizing reaction, or by exposure to a mild oxygen or argon plasma, resulting in patterned thin barrier film 40b. Exposure of the etch-resistant monolayer 43 during typically a few seconds to an oxygen plasma or during typically a few minutes to an argon plasma at 0.25 mbar and 300 W in an inductively coupled plasma chamber may be sufficient to remove the monolayer 43.

In some cases, however, the etch-resistant monolayer 43 can be left as a passivating layer, provided that it has reduced or substantially no preferential or significant adsorptivity to the substrate to be printed or patterned. This will be further described in relation to the examples, and in relation to FIG. 7.

It is herein observed that such a passivating layer may be provided on the barrier layer in other ways as well than as a monolayer with a second stamp. The passivating layer may be obtained by self-aligned deposition after the completion of the patterning of the barrier layer. This is an option due to the difference in surface activity between the barrier layer 41 and the stamp body 31. Particularly monolayers may be adhered to the barrier layer selectively. The adhesion may both be physical and chemical; one example of chemical adhesion is for instance the application of a polymerisable compound and the polymerization thereof, whereby the barrier layer is included in the polymeric network. A further example is the provision of a polymer and the subsequent cross-linking thereof with the barrier layer.

Alternatively, the passivating layer may be applied on the complete surface before patterning of the barrier layer. Suitable chemistries include esters, imides, sol-gel compounds and the like. The patterning of the barrier layer and the passivating layer is then achieved with a single photolithographic mask.

In a third modification, the passivating layer is applied after patterning of the barrier layer and is patterned subsequently according to the same pattern as the barrier layer.

It is furthermore observed that the combination of barrier layer and passivating layer is not limited to those embodiments, in which the barrier layer is applied as a thin layer onto the mould. Contrarily, the use of a passivating layer is particularly suitable in the event that the barrier layer is formed by modification of the first material.

Additionally, the passivating layer may be chosen to have a specific surface activity. Dependent on the choice of the reagent, this may be used to render those areas hydrophilic or hydrophobic, or to provide it with other characteristics that may be employed for selective adsorption of an ink. Such characteristics include for instance the acidity, the polarity, the electrical conductivity.

A plurality of materials may be applied as a passivating layer. Examples include a monolayer compound such as an alkanethiol, a silane, a trimethoxysilane, a trichlorosilane, an acid such as a phosphonic acid, a sulphonic acid or a carboxylic acid, an activated acid such as an acid chloride. Such functional groups may be used for binding to the modified PDMS. Alternatively, the monolayer comprises more than one, particularly two functional groups: one for binding to the second material, and another to provide a modified surface structure. In such a case, it is however important to select such materials that do not or not substantially adsorb to the non-modified portion of the surface. In case adsorption to the non-modified portion of the surface cannot be avoided, it should be reversible and sufficiently less strong than to the modified portion of the surface, such that the adsorbed material can subsequently be removed selectively from the non-modified areas to provide only the modified portion of the surface with a passivating layer. The passivating layer may alternatively be a metal or a metal compound such as a metal oxide. In a suitable embodiment, the metal or alloy is provided by electroless deposition.

FIGS. 7A-E show in cross-sectional, diagrammatical views a further embodiment of the invention. The view is not on scale.

FIG. 7A shows a first step in the method, in which a stamp body 31 is provided. The stamp body 31 is preferably provided by moulding and is provided with a surface 3. It comprises a first material.

FIG. 7B shows a second step in the method, in which the stamp body 31 is provided at its surface 3 with a photolithographic mask 41. The mask 41 is suitably an adequate photoresist, but may alternatively be a nitride, an oxide or other hard mask.

FIG. 7C shows the result of a third step. Herein the stamp body 31 is at its surface 3 locally modified to form a filler 36. This filler 36 is particularly a barrier layer. However, the barrier layer 36 or any layer thereon, may be applied as the printing region. One suitable example of a barrier layer is an oxide. This barrier layer is in this example obtained by modification of the first material, for instance with an oxide plasma. This oxide is more hydrophilic than the stamp 30, particularly a stamp comprising polydimethylsiloxane (PDMS). It may therefore be used as a barrier against transfer of apolar materials. Experiments have shown, however, that due to cracking of the oxide layer, the barrier is not sufficiently effective.

FIG. 7D shows the result of a fourth step, that is used to solved the stated problem: a passivating layer 43 is applied on the barrier layer 36. It was found, that after provision of the oxide barrier layer 36 with a suitable passivating layer, for instance a fluorosilane, the bilayer of barrier layer 36 and passivating layer 43 constitutes an accurate barrier against transfer of apolar materials. Experiments carried out indicate that the passivating layer may close cracks in the second material, particularly the oxide of the stamp materials. Such cracks tend to appear as a result of stress during the printing operation. Patterns have been transferred substantially adequate with the passivating layer.

A further reason to cover the oxide layer 36 with a passivating layer 43 is the instability of the oxide layer in ambient air, as a consequence of which the oxide layer 36 becomes increasingly apolar over time. Preferably, both the oxide layer 36 and the passivation layer 43 are monolayers or multilayers of a few number of molecules only. The resulting stack is thus preferably less than 50 nm, and the extension above the surface 3 of the stamp body 31 is even less.

Additionally, it was found that flat stamps 30 of the invention provided with the passivating layer 43, may be used for the transfer of inks of relatively small molecules, such as octanethiol. Small molecules are particularly organic compounds having a chain length of less than 15 and most suitably at most 10 groups, such as CH₂, CO, NH, O, or alike or any combination of them. These may for instance be alkanethiols, but alternatively silanes with suitable functional groups, such as amino-substituted silanes. There is a desire for printing such molecules, as these are very suitable for use as adhesion promoters.

FIG. 7E shows the result after removal of the mask 41. A stamp 30 is obtained that comprises first regions 37 of the first material and second regions 38 of the second material at the surface 3 of the stamp body 31. The second regions are herein covered with an additional passivating layer 43.

Here again, though much less preferable than the above described embodiments, the printing and blocking materials can be reversed, i.e. the mould 31 can be made of blocking material and the thin film of second material or of third material (passivating layer) 40b can be made of printing material. It is due to the limited thickness, which typically may be 100 nm or less, preferably 50 nm or less, most preferably 20 nm or less of the film 40b that this embodiment fimctions. Due to this limited thickness, the sidewalls of the film 40b do not substantially transfer any unwanted printing compound onto the substrate to be printed.

It is to be understood that although preferred embodiments, specific constructions and configurations, as well as materials, have been discussed herein for devices according to the present invention, various changes or modifications in form and detail may be made without departing from the scope and spirit of this invention. For example, instead of completely filling voids between protruding printing regions, as in the first embodiment, the mould with the protruding elements made from the first material suitable for printing the printing compound, may be coated with a second material suitable for blocking the printing compound (not represented in the drawings). The second material may then subsequently be removed, for example by CMP or in any other suitable way, from the surface of the protruding elements, thus freeing the surface of the printing regions for transferal of the printing compound towards a substrate to be printed. The coating at the sides of the protruding printing elements significantly reduce or prevent sideways extrusion of printing compound from the printing regions, thus significantly reducing or preventing sideways enlargement of the printed area. This way, less of the second material needs to be applied in case of for example large non-printing or blocking regions in the stamp.

### EXAMPLE 1

On a flat piece of PDMS a hydrophilic pattern of oxidized areas was created by exposure of the mask-protected stamp to an oxygen plasma. The stamp material used was Sylgard-184 poly(dimethylsiloxane) (PDMS) as obtained from Dow Coming. It was mixed in a 1:10 curing agent/prepolymer ratio and cured overnight at 60° C. The local oxidation was carried out with a plasma treatment (Tepla 300E microwave oxygen plasma, 300 W, 0.25 mbar O₂ for 30 seconds) through a contact mask.

The mask consisted of narrow slits, measuring approximately 3 μm in length and 600 nm across. Apolar n-octadecanethiol (ODT) was used to ink the stamp. It was found that there is selectivity of ink transfer, which was tested by printing and subsequently etching gold samples. However, the expected individual pores were found to be interspersed with unexpected and almost parallel lines of intact gold. The morphology of these lines (regarding regularity and anisotropy) indicates that they are the result of ink transport at a location of stress induced cracks in the brittle, silica alike, oxidized PDMS layer. This stress may result from mechanical deformation (externally applied stress) or from compression of the surface upon oxidation. In view of the orientation of the lines, the origin appears to be mechanical deformation.

### EXAMPLE 2

On a flat piece of PDMS a hydrophilic pattern of oxidized areas was created by exposure of the mask-protected stamp to an oxygen plasma in the manner as described in Example 1. The mask consisted of narrow slits, measuring approximately 3 μm in length and 600 nm across. Then, the oxidized areas were modified by exposure to an agent, such as a reactive fluorosilane or polyethyleneglycol. In this example, use was made of 1H,1H,2H,2H-perfluorodecyltrichlorosilane (PTS). An alternative agent is for instance undecyltrichlorosilane.

These PTS-modified flat stamps were used to transfer patterns of n-octadecanethiol (ODT, 98% purity), 16-mercaptohexadecanoic acid (MHDA, 90% purity) and octanethiol (OT, 98.5% purity), as purchased from Sigma-Aldrich. The ink was used in a high concentration in ethanol, i.e. 10 mM (ODT and MHDA) or 1 mM (OT). The patterns were transferred to gold substrates. Ink was applied freshly on the stamps, which had been prepared up to six months earlier. The ink was transferred, and used as a resist layer on gold. The gold was developed subsequently. The handling of PTS-treated oxidized PDMS stamps was identical to the stamps of Example 1. PTS-modified stamps could be used for more than 6 months without a change in performance.

The quality of the etched substrates was identical for the ODT and the MHDA patterns. The patterns of the barrier layer on the stamp corresponded to the etched portions of the gold. The distribution of the dimensional size (length and width) of the etched portions of the gold closely matched the manufacturer's specifications of the mask that was used for selective oxidation, having an average width of 600 nm and a standard deviation of less than 100 nm. Even with a contact time as long as one minute virtually no blurring of the pattern was observed when using either MHDA or ODT ink. The PTS modification appears to inhibit effectively ink penetration through cracks in the oxide layer. Comparison with the results of Experiment 3, shows that the PTS passivating layer prevents surface spreading of the MHDA ink more effectively than a standard ambient air (void) barrier. In such a relief stamp, the 600 nm would have been annihilated within one minute.

The results for OT patterning seemed, at first glance, less impressive for the OT patterns. A significant number of defects in the etched gold substrate were found. Comparison with a cm-AFM image of the mask, which was used for selective stamp oxidation, nevertheless reveals that the demarcation of the modified areas closely follows the dimensions of the holes in the mask. The reason for the result is the low etch resistance of the very thin octanethiol monolayer and the high mobility of the octanethiol molecules. In view of the low molecular mass, short chain alkanethiols exhibit relatively large vapor pressures. Therefore, no direct contact between stamp and surface is needed for thiol transfer. However, the transport of the alkanethiol in the gas phase is with the stamp of the invention still rather limited; due to its flatness gas phase transport is impossible when the patterned stamp is in contact with the substrate.

### EXAMPLE 3

### Not According to the Invention

A standard relief stamp was used for the transfer of MHDA ink to a gold substrate in the manner indicated in Example 2. The stamp was held in contact with the substrate for several contact times. With a contact time of 15 seconds, the feature width is 4 μm. With a contact time of 45 seconds, the feature width is 4.5 μm. With a contact time of 105 seconds, the feature width is 5.5 μm. With a contact time of 195 seconds, the feature width is 10 μm. This results therein that 1 minute of contact with such a stamp results in approximately 2 μm lateral decrease in feature size.

### EXAMPLE 4

On a flat piece of PDMS a hydrophilic pattern of oxidized areas was created by exposure of the mask-protected stamp to an oxygen plasma in the manner as described in Example 1. A pattern of hydrophilic dots measuring approximately 500 nm in diameter and arranged in mutually perpendicular bundles of parallel ribbons, was created on a flat piece of PDMS by local oxidation. Hydrophilic and fluorescent tetramethylrhodamine-5-(and-6-)-isothiocyanate (TRITC) was applied to the stamp as an ink. The stamp was used for provision of a pattern on a glass substrate.

Inspection of the glass substrate using fluorescence microscopy revealed a pattern, which showed a higher fluorescence intensity in the regions corresponding to the oxidized areas of the stamp than in the other regions corresponding to the non-oxidized areas of the stamp. This indicates a preferred transfer of TRITC molecules from the oxidized areas, presumably due to a higher surface concentration in these areas. There was, however, also TRITC present on the non-oxidized areas.

1. A soft lithographic stamp (30) for use with a printing compound to generate a printed area on a substrate, the soft lithographic stamp (30) provided with a stamp body, at a surface of which stamp body a first region with a first material and a second region with a second material are present, one of which first and second regions corresponds to the printed area to be generated, and of which the first material has a bulk in the stamp body, wherein the second material (36) abuts the first material for preventing of sideways enlargement of the printed area and wherein the second material (36) possesses a storage capability and an adsorption capability for the printing compound that are different from those of the first material, such that on printing the printing compound is transferred selectively from either the first or the second region to the substrate, so as to generate the printed area.

2. A soft lithographic stamp (30) as claimed in claim 1, wherein the second material is obtainable by modification of the first material in the second region only.

3. A soft lithographic stamp (30) as claimed in claim 2, wherein a passivating layer for the second material is present on the surface of the second region of the stamp body.

4. A soft lithographic stamp (30) as claimed in claim 3, wherein the passivating layer has a surface activity that is different from the surface activity of the first region.

5. A soft lithographic stamp (30) as claimed in claim 1, wherein:
the first region acts as a printing region (38) that is provided with a bulk, the first material exhibiting a storage capability for the printing compound in the bulk, and
the second region acts as a blocking region (37) for the printing compound, and said second material (36) exhibits substantially no storage nor adsorption capability for the printing compound,

6. A soft lithographic stamp (30) according to claim 5, the stamp (30) comprising a mould (31) with protruding elements (32), mould and protruding elements being formed from said first respectively second material, wherein spaces between the protruding elements are filled with said second respectively first material.

7. A soft lithographic stamp (30) according to claim 4, wherein there is a further region obtainable by modification of the first material, which is provided with a further passivating layer having a surface activity different from that of the first and second regions, such that a first printing compound is selectively adsorbed by and printable from the first region and a further printing compound is selectively adsorbed by and printable from the further region.

8. A soft lithographic stamp (30) according to claim 6, wherein the printing regions (38) and the blocking regions (37) are formed of a patterned film (40b) of the second respectively first material on a mould of the first respectively second material.

9. A soft lithographic stamp (30) according to claim 8, wherein the patterned film has a thickness of 100 nm or less.

10. A printing apparatus comprising a soft lithographic stamp as claimed in claim 1, said apparatus having means for locally providing pressure on a side of the stamp facing away from the surface with the first and the second regions, such that selected portions of the surface of the stamp can be displaced individually towards a substrate for transferring a printing compound.

11. A method for forming a soft lithographic stamp (30) for use with a printing compound to generate a printed area, the method comprising:
providing a moulded stamp body from a first material, which stamp body is provided with a surface;
providing a second material in a patterned manner so as to constitute first regions and second regions on the surface of the stamp body, in which first regions the first material is present at the surface and in which second regions the second material is present at the surface,
wherein the second material (36) abuts the first material so as to prevent sideways enlargement of the printed area and is chosen to possess a storage capability and an adsorption capability for the printing compound that are different from those of the first material.

12. A method according to claim 11, wherein the moulded stamp body (31) is formed with protruding elements (32) and the second material is provided by filling spaces between said protruding elements (32) therewith.

13. A method according to claim 11, wherein the second material is provided by local modification of the first material.

14. A method according to claim 13, wherein the second material is subsequently covered with a passivating layer of a third material.

15. A method of selectively providing barrier material on the second material of the stamp as manufactured according to claim 13.

16. Use of the stamp as claimed in claim 1 for the generation of a printed area on a substrate.

17. Use of the printing apparatus as claimed in claim 10 for the generation of a printed area on a substrate, wherein selected portions of the stamp are displaced towards the substrate individually in a wave-shaped movement.

18. A method of manufacturing an electronic device comprising the step of generating a printed area on a substrate according to claim 16.
